(19) United States
(12) Patent Application Publication
(10) Pub. No.: US 2007/0181899 A1
(43) Pub. Date: Aug. 9, 2007

(54) Light emitting diode package

(75) Inventors: Min Sang Lee, Daegu (KR); Byung Man Kim, Cheonan (KR); Seon Goo Lee, Gunpo (KR); Dong Yeoul Lee, Suwon (KR); Alex Chae, Seongnam (KR); Je Myung Park, Siheung (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/646,424

(22) Filed: Dec. 28, 2006

(30) Foreign Application Priority Data
Feb. 7, 2006 (KR) 10-2006-0011595

(51) Int. Cl. H01L 33/00

(52) U.S. Cl. 257/99; 257/E33.058

(57) ABSTRACT

Provided an LED package comprising a first package composed of a first region serving as a first electrode and a second region which is formed so as to overlap a portion of the first region, the second region defining a molding material filling cavity; one or more LED chips mounted on the first region of the first package; a second package formed under the second region of the first package, the second package being insulated by the first region and an insulating member so as to serve as a second electrode; conductive wire for electrically connecting the LED chips and the second package; and a molding material filled inside the second region of the first package so as to protect the LED chips and the conductive wire. The first and second packages are formed of aluminum.

### CROSS-REFERENCE TO RELATED APPLICATIONS

This application claims the benefit of Korean Patent Application No. 10-2006-0011595 filed with the Korean Intellectual Property Office on Feb. 7, 2006, the disclosure of which is incorporated herein by reference.

### BACKGROUND OF THE INVENTION

1. Field of the Invention

The present invention relates to a light emitting diode package which prevents the compound reaction between a package composed of a pair of electrodes and a fluorescent compound coming in contact with the package.

2. Description of the Related Art

A light emitting diode (hereinafter, referred to as the LED) is a semiconductor element in which light emitting sources are formed by changing compound semiconductor materials such as GaAs, AlGaAs, GaN, InGaInP and the like, thereby implementing various colors of light.

Recently, as a semiconductor technology rapidly develops, it has become possible to manufacture high-brightness and high-quality LED elements. Further, as the implementation of blue and white diodes with high characteristics is realized, the application of the LED elements is extended as a display and next-generation light source. For example, surface-mounted LED packages are manufactured.

Hereinafter, a conventional LED package will be described in detail with reference to FIGS. 1 and 2.

FIG. 1 is a schematic view illustrating a conventional LED package. The conventional surface-mounted LED package includes a package 20 formed of molding epoxy resin. A predetermined surface of the package 20 is provided with an emission window (not shown) which is opened so that light is easily emitted. On a different surface thereof, a portion of a lead frame 50 composed of a pair of lead terminals is formed so as to project, the portion of the lead frame 50 being mounted on an external circuit of a printed circuit board or the like. Further, inside the package 20 constructed in such a manner, the light emitting surface of an LED chip (not shown) is disposed so as to face the emission window (not shown), and the lead frame 50 and the LED chip are connected to each other by wire (not shown).

FIG. 2 is a sectional view taken along I-I′ line of FIG. 1, illustrating the detailed structure of the conventional LED package.

As shown in FIG. 2, the conventional surface-mounted LED package includes a plurality of lead frames 50, each lead frame composed of a pair of lead terminals; the package 20 formed of synthetic resin so as to house a portion of the lead frame 50 therein; one or more LED chips 60 mounted on the lead frames 50 inside the package 20; conductive wire 70 for electrically connecting the LED chips 60 and the lead frames 50; and a molding material 80 filled in the package 20 so as to protect the LED chips 60 and the wire 70.

The molding material 80 for protecting the LED chips is formed of optically-transparent resin including a transparent material or fluorescent body, depending on the color of LED chip to be implemented. Further, in order to enhance heat radiation, the lead frame 50 is formed of copper. Simultaneously, in order to enhance reflectance, a silver-plated layer 10 is formed on one surface of the lead frame 50 coming in contact with the molding material 80.

The silver-plated layer 10 of the surface-mounted LED package has an advantage of enhancing light-extraction efficiency by enhancing reflectance. However, the silver-plated layer 10 reacts with the molding material 80 such that the reliability thereof is reduced. Therefore, the selection of molding material, that is, the selection of fluorescent body depending on the color of a LED chip is limited.

Further, when a fluorescent body which hardly reacts with the silver-plated layer 10 is applied, the light-conversion efficiency decreases so that a relative light intensity is reduced. Further, color gamut is reduced. Therefore, the use of the LED package is limited.

Further, in the conventional surface-mounted LED package, heat generated from the LED chip is radiated through a medium such as the molding material. Therefore, heat radiation is not efficient, thereby reducing the performance of the LED chip and a life span thereof.

### SUMMARY OF THE INVENTION

An advantage of the present invention is that it provides an LED package in which a package composed of a pair of electrodes, on which LED chips are mounted, is formed of aluminum or an alloy thereof, thereby minimizing the compound reaction with a molding material coming in contact with the package and enhancing heat-radiation efficiency.

Additional aspect and advantages of the present general inventive concept will be set forth in part in the description which follows and, in part, will be obvious from the description, or may be learned by practice of the general inventive concept.

According to an aspect of the invention, an LED package comprises a first package composed of a first region serving as a first electrode and a second region which is formed so as to overlap a portion of the first region, the second region defining a molding material filling cavity; one or more LED chips mounted on the first region of the first package; a second package formed under the second region of the first package, the second package being insulated by the first region and an insulating member so as to serve as a second electrode; conductive wire for electrically connecting the LED chips and the second package; and a molding material filled inside the second region of the first package so as to protect the LED chips and the conductive wire. The first and second packages are formed of aluminum.

According to another aspect of the invention, the first and second regions of the first package are integrally formed through a die-casting process.

According to a further aspect of the invention, the surfaces of the first region of the first package and the second package are electro-polished so as to serve as an electrode and reflecting layer or are plated with any one of gold, silver, copper, platinum, palladium, and an alloy thereof.

According to a still further aspect of the invention, the molding material is formed of one selected from a group consisting of transparent epoxy, silicon, and a fluorescent compound so as to protect the LED chip mounted on the first package and the conductive wire and simultaneously transmit light emitted from the LED chip outside. The fluorescent compound is formed of one selected from a group consisting of an oxide fluorescent compound, a silicate fluorescent compound, a nitride fluorescent compound, and a sulfide fluorescent compound.

According to a still further aspect of the invention, the LED package further comprises an alignment margin key formed of an insulating member within the first region of the first package in order to align the first and second packages.

According to a still further aspect of the invention, the LED package further comprises a heat sink formed on the bottom surface of the first region and the bottom surface of the second package. The heat sink is formed on the bottom surface of the first region and the bottom surface of the second package with a bonding layer interposed therebetween.

According to a still further aspect of the invention, the heat sink is formed of copper or aluminum.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a schematic view illustrating the structure of a conventional LED package;

FIG. 2 is a sectional view taken along I-I′ line of FIG. 1;

FIG. 3 is a front view illustrating the structure of an LED package according to a first embodiment of the present invention;

FIG. 4 is a sectional view taken along III-III′ line of FIG. 3;

FIG. 5 is a front view illustrating the structure of an LED package according to a second embodiment of the invention; and

FIG. 6 is a front view illustrating the structure of an LED package according to a third embodiment of the invention.

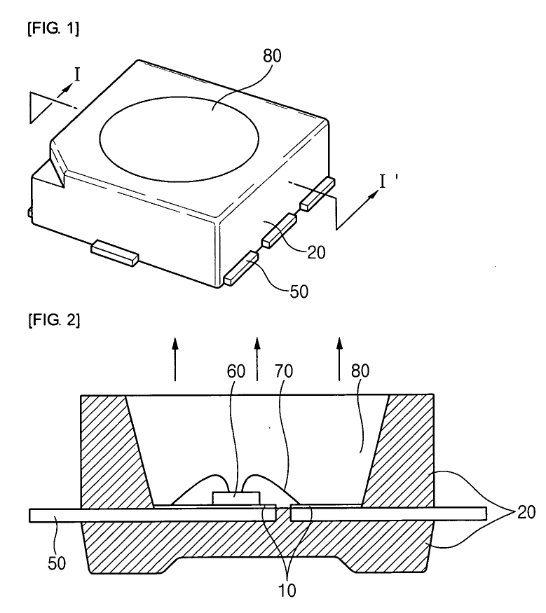

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, an LED package according to the present invention will be described in detail with reference to the accompanying drawings.

### First Embodiment

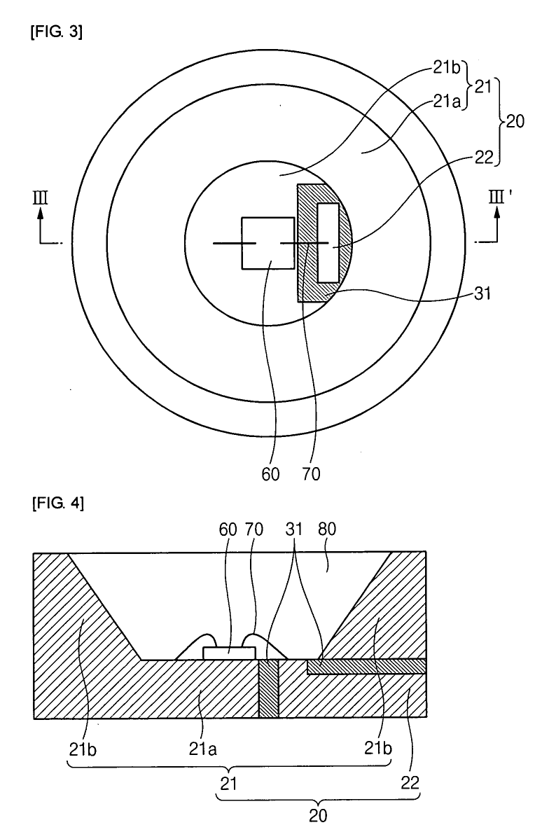

First, an LED package according to a first embodiment of the invention will be described in detail with reference to FIGS. 3 and 4. FIG. 3 is a front view illustrating the structure of the LED package according to the first embodiment of the invention, and FIG. 4 is a sectional view taken along III-III′ line of FIG. 3, illustrating the detailed structure of the LED package according to the first embodiment.

Referring to FIGS. 3 and 4, the package 20 according to the first embodiment of the invention includes a first package 21 and a second package 22. The first package 21 is composed of a first region 21a serving as a first electrode and a second region 21b formed so as to overlap a portion of the first region 21a, the second region 21b defining a molding material filling cavity. The second package 22 is formed under the second region 21b of the first package 21 and is insulated from the first region 21a through an insulating member 31 so as to serve as a second electrode.

The first and second regions 21a and 21b composing the first package 21 are integrally formed by die-casting. In this case, a manufacturing process of the first package 21 can be simplified.

The package 20 according to the invention, including the first and second packages 21 and 22, is formed of electro-polished aluminum or an alloy thereof, serving as a reflecting member.

In other words, the first and second packages 21 and 22 are formed of aluminum or an alloy thereof. Therefore, it is possible to enhance the light extraction efficiency of the LED package without a separate reflecting member such as the conventional sliver-plated layer 10 (refer to FIG. 2).

Since the package 20 is formed of thermally-conductive aluminum or an alloy including aluminum, heat generated in an LED is radiated through the entire surface of the package 20. Therefore, it is possible to obtain a more excellent heat-radiation effect than the conventional LED package in which heat is radiated by using only a medium, such as a molding material, and a lead frame.

On the first region 21a of the first package, one or more LED chips 60 are mounted. The LED chips 60 are wire-bonded to the second package 22 serving as the second electrode so as to be electrically connected thereto through conductive wire 70.

Preferably, the surfaces of the first region 21a and the second package 22 are electro-polished or are plated with any one of gold, silver, copper, platinum, palladium, and an alloy thereof such that the functions thereof as an electrode and reflecting layer can be smoothly performed.

Inside the package 20 having the LED chips 60 and the conductive wire 70 formed therein, or more specifically, inside the second region 21b of the first package 21, a molding material 80 is filled so as to protect the LED chips 60 and the conductive wire 70 from the external environment.

The molding material 80 is formed of any one of transparent epoxy, silicon, and fluorescent compound. The molding material serves to radiate some of heat generated by the LED chip 60. In other words, the molding material radiates heat, excluding the heat radiated through the package 20, to the outside.

The package 20 coming in contact with the molding material 80 is formed of aluminum or an alloy including aluminum. Therefore, as for the fluorescent compound forming the molding material 80, any one of an oxide fluorescent compound, a silicate fluorescent compound, a nitride fluorescent compound, and a sulfide fluorescent compound may be used.

According to the invention, since the package 20 is formed of aluminum or an alloy thereof, an oxide fluorescent compound, a silicate fluorescent compound, and a nitride fluorescent compound can be all used. Particularly, a sulfide fluorescent compound with an excellent color gamut can be also used without a compound reaction at the joining interface with the package 20.

### Second Embodiment

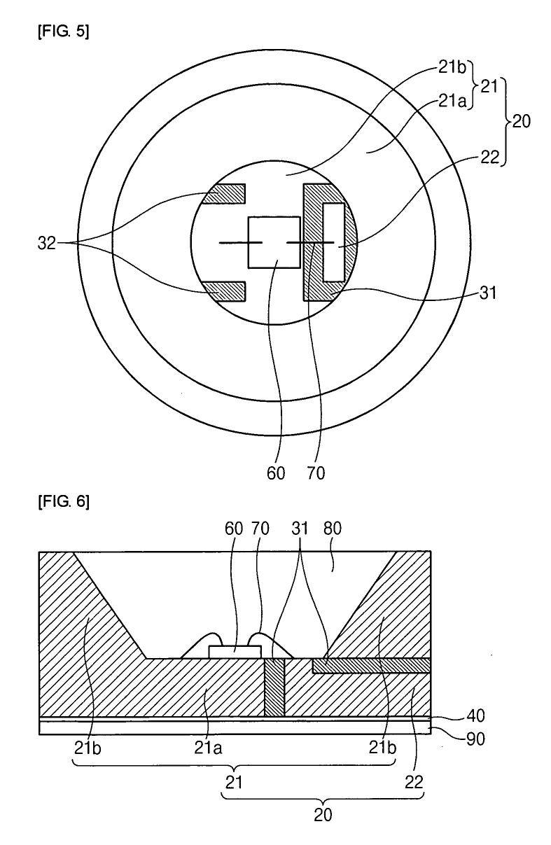

Then, a second embodiment of the invention will be described with reference to FIG. 5. In this case, the descriptions of the same components as the first embodiment will be omitted.

FIG. 5 is a front view illustrating the structure of an LED package according to the second embodiment of the invention.

As shown in FIG. 5, the LED package according to the second embodiment has almost the same construction as the first embodiment. However, the LED package further includes an alignment margin key 32 for aligning the second package 22 to the first package 21, when the second package 22 serving as a second electrode is combined inside the first region 21a of the first package 21.

The LED package according to the second embodiment has the same effect and operation as the first embodiment. Further, the LED package according to the second embodiment is provided with the alignment margin key 32 for forming the second package, thereby preventing misalignment when the first and second packages 21 and 22 are coupled to each other, which means a more excellent effect can be obtained than in the first embodiment.

### Third Embodiment

Referring to FIG. 6, a third embodiment of the invention will be described. In this case, the descriptions of the same components as the first embodiment will be omitted.

FIG. 6 is a sectional view illustrating the structure of an LED package according to the third embodiment of the invention.

As shown in FIG. 6, the LED package according to the third embodiment has almost the same construction as that of the LED package according to the first embodiment (refer to FIG. 4). However, the LED package according to the third embodiment further includes a heat sink 90 formed of copper or aluminum on the bottom surface of the first region 21a of the first package 21 and the bottom surface of the second package 22.

The heat sink 90 is formed on the bottom surfaces of the first region 21a and the second package 22, with a bonding layer 40 interposed therebetween. Preferably, the bonding layer 40 is formed of a thermally-conductive material with a small thickness.

The LED package according to the third embodiment has the same effect and operation as the first embodiment. Further, the LED package according to the third embodiment can obtain a more excellent radiation effect than the LED package according to the first embodiment.

In this embodiment, the technical idea of the invention, where the package is formed of aluminum or an alloy thereof in order to enhance a radiation effect and the compound reaction between the surface of the package serving as an electrode and the molding material is prevented from occurring, has been applied to a top-view LED package for description. However, the technical idea may be applied to a side-view LED package.

As described above, the package is formed of aluminum or an aluminum alloy. Therefore, as for the molding material, an oxide fluorescent compound, a silicate fluorescent compound, a nitride fluorescent compound, and a sulfide fluorescent compound can be all used, which are fluorescent compounds with an excellent color gamut.

Further, since the package is formed of aluminum or an aluminum alloy, it is possible to enhance heat radiation efficiency.

Therefore, it is possible to provide an LED package which increases color gamut by minimizing the compound reaction with the molding material and has excellent heat-radiation efficiency.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An LED package comprising:
a first package composed of a first region serving as a first electrode and a second region which is formed so as to overlap a portion of the first region, the second region defining a molding material filling cavity;
one or more LED chips mounted on the first region of the first package;
a second package formed under the second region of the first package, the second package being insulated from the first region through an insulating member so as to serve as a second electrode;
a conductive wire for electrically connecting the LED chips and the second package; and
a molding material filled inside the second region of the first package so as to protect the LED chips and the conductive wire,
wherein the first and second packages are formed of aluminum.

2. The LED package according to claim 1,
wherein the first and second packages are formed of an aluminum alloy.

3. The LED package according to claim 1,
wherein the first and second regions of the first package are integrally formed.

4. The LED package according to claim 1,
wherein the surfaces of the first region of the first package and the second package are electro-polished.

5. The LED package according to claim 1,
wherein the surfaces of the first region of the first package and the second package are plated with any one of gold, silver, copper, platinum, palladium, and an alloy thereof.

6. The LED package according to claim 1,
wherein the molding material is formed of one selected from a group consisting of transparent epoxy, silicon, and a fluorescent compound.

7. The LED package according to claim 6,
wherein the fluorescent compound is formed of one selected from a group consisting of an oxide fluorescent compound, a silicate fluorescent compound, a nitride fluorescent compound, and a sulfide fluorescent compound.

8. The LED package according to claim 1 further comprising
an alignment margin key formed of an insulating member within the first region of the first package in order to align the first and second packages.

9. The LED package according to claim 1 further comprising
a heat sink formed on the bottom surface of the first region and the bottom surface of the second package.

10. The LED package according to claim 9,
wherein the heat sink is formed on the bottom surface of the first region and the bottom surface of the second package with a bonding layer interposed therebetween.

11. The LED package according to claim 9,
wherein the heat sink is formed of copper or aluminum.
